(19) United States
(12) Patent Application Publication
(10) Pub. No.: US 2025/0212618 A1
(43) Pub. Date: Jun. 26, 2025

(54) DISPLAY PANEL AND METHOD OF MANUFACTURING THE SAME

(71) Applicant: Samsung Display Co., Ltd., Yongin-si (KR)

(72) Inventors: MINWOO WOO, Yongin-si (KR); SUNGHO KIM, Yongin-si (KR); KWANHEE LEE, Yongin-si (KR); SEUNGHYUN LEE, Yongin-si (KR); WANGWOO LEE, Yongin-si (KR); JISEON LEE, Yongin-si (KR); HYERI CHO, Yongin-si (KR)

(21) Appl. No.: 18/954,201

(22) Filed: Nov. 20, 2024

(30) Foreign Application Priority Data
Dec. 26, 2023 (KR) 10-2023-0191549

(51) Int. Cl. H10K 59/122; H10K 59/12

(52) U.S. Cl. CPC H10K 59/122; H10K 59/1201

(57) ABSTRACT

A display panel includes a base layer, a barrier wall above the base layer, and including a first barrier wall and a second barrier wall, a pixel definition layer above the base layer, and defining a light-emitting opening overlapping the first barrier wall, and surrounded by the second barrier wall in plan view, and a light-emitting element including an anode above the barrier wall, a light-emitting pattern above the anode and the pixel definition layer, and a cathode above the light-emitting pattern, and contacting the second barrier wall.

### CROSS-REFERENCE TO RELATED APPLICATION

The present application claims priority to, and the benefit of, Korean Patent Application No. 10-2023-0191549, filed on Dec. 26, 2023, in the Korean Intellectual Property Office, the entire disclosure of which is incorporated herein by reference.

### BACKGROUND

### 1. Field

The present disclosure relates to a display panel with improved display quality, and a method of manufacturing the display panel.

### 2. Description of Related Art

Display devices that provide images to a user, such as a television set, a monitor, a smart phone, and a tablet computer, include a display panel to display the images. Various types of display panels, such as a liquid crystal display panel, an organic light-emitting display panel, an electrowetting display panel, and an electrophoretic display panel, are being developed.

The organic light-emitting display panel includes an anode, a cathode, and a light-emitting pattern. The light-emitting pattern is divided into portions to be located in light-emitting areas, and the cathode provides a common voltage to each light-emitting area.

### SUMMARY

The present disclosure provides a display panel with improved display quality, which includes a light-emitting element formed without using a metal mask.

The present disclosure provides a method of manufacturing the display panel.

Embodiments of the present disclosure provide a display panel including a base layer, a barrier wall above the base layer, and including a first barrier wall and a second barrier wall, a pixel definition layer above the base layer, and defining a light-emitting opening overlapping the first barrier wall, and surrounded by the second barrier wall in plan view, and a light-emitting element including an anode above the barrier wall, a light-emitting pattern above the anode and the pixel definition layer, and a cathode above the light-emitting pattern, and contacting the second barrier wall.

The second barrier wall may surround the first barrier wall, and may be spaced apart from the first barrier wall, in plan view.

The first and second barrier walls may include a conductive material.

The first and second barrier walls may include a first barrier wall layer above the base layer, and a second barrier wall layer above the first barrier wall layer.

The first barrier wall layer of the second barrier wall may have an undercut shape with respect to the second barrier wall layer of the second barrier wall.

The second barrier wall layer of the second barrier wall may protrude toward the light-emitting opening to a greater degree than the first barrier wall layer of the second barrier wall.

The cathode may contact an inner side surface of the first barrier wall layer of the second barrier wall.

The barrier wall may define a barrier wall opening overlapping the light-emitting opening with the first barrier wall therein.

A portion of the pixel definition layer defining the light-emitting opening may be in the barrier wall opening.

The display panel may further include a lower encapsulation inorganic pattern above the cathode, covering the light-emitting element, and filled in the barrier wall opening.

The display panel may further include a sacrificial pattern between the pixel definition layer and the anode.

Embodiments of the present disclosure provide a method of manufacturing a display panel, the method including providing a preliminary display panel including a base layer, a preliminary barrier wall above the base layer, an anode layer above the preliminary barrier wall, and a sacrificial layer, etching the sacrificial layer to form a preliminary sacrificial pattern, etching the anode layer to form an anode, first etching the preliminary barrier wall to form a first barrier wall and a second preliminary barrier wall, depositing a preliminary pixel definition layer above the base layer, etching the preliminary pixel definition layer to form a pixel definition layer defining a light-emitting opening overlapping the first barrier wall, and an opening exposing an inner side surface of the second preliminary barrier wall, second etching the preliminary barrier wall to form a second barrier wall defining a barrier wall opening, and forming a light-emitting pattern and a cathode overlapping the barrier wall opening.

The method may further include etching the preliminary sacrificial pattern to form a sacrificial pattern defining a sacrificial opening overlapping the light-emitting opening.

The first barrier wall and the second barrier wall may include a first barrier wall layer above the base layer, and a second barrier wall layer above the first barrier wall layer.

The second barrier wall layer of the second barrier wall may protrude toward the light-emitting opening to a greater degree than the first barrier wall layer of the second barrier wall.

The forming of the light-emitting pattern and the cathode may include thermally evaporating a light-emitting layer on the anode and the pixel definition layer, and sputtering a cathode layer on the light-emitting pattern.

The sputtering of the cathode layer may include depositing the cathode layer to contact an inner side surface of the first barrier wall layer of the second barrier wall.

The second etching of the preliminary barrier wall may include etching the second preliminary barrier wall to allow the first barrier wall to be in the barrier wall opening.

The second barrier wall may surround the first barrier wall, and may be spaced apart from the first barrier wall in plan view.

The method may further include forming a lower encapsulation inorganic pattern on the cathode.

According to the above, the process of etching the barrier wall using a photoresist layer (the process of forming the tip portion), the process of forming an outgassing opening, the process of forming the light-emitting opening, the process of forming the sacrificial opening are integrated. That is, the process of etching the barrier wall (the process of forming the tip portion), the process of forming the outgassing opening, the process of forming the light-emitting opening, and the process of forming the sacrificial opening are performed using one mask, and thus, the number of masks suitable to manufacture the display panel is reduced.

### BRIEF DESCRIPTION OF THE DRAWINGS

The above and other aspects of the present disclosure will become readily apparent by reference to the following detailed description when considered in conjunction with the accompanying drawings wherein:

FIG. 1A is a perspective view of a display device according to one or more embodiments of the present disclosure;

FIG. 1B is an exploded perspective view of a display device according to one or more embodiments of the present disclosure;

FIG. 2 is a cross-sectional view of a display module according to one or more embodiments of the present disclosure;

FIG. 3 is a plan view of a display panel according to one or more embodiments of the present disclosure;

FIG. 4 is an enlarged plan view of a portion of a display area of a display panel according to one or more embodiments of the present disclosure;

FIG. 5 is a cross-sectional view taken along the line I-I′ of FIG. 3; and

FIGS. 6A to 6N are cross-sectional views illustrating processes of a method of manufacturing a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

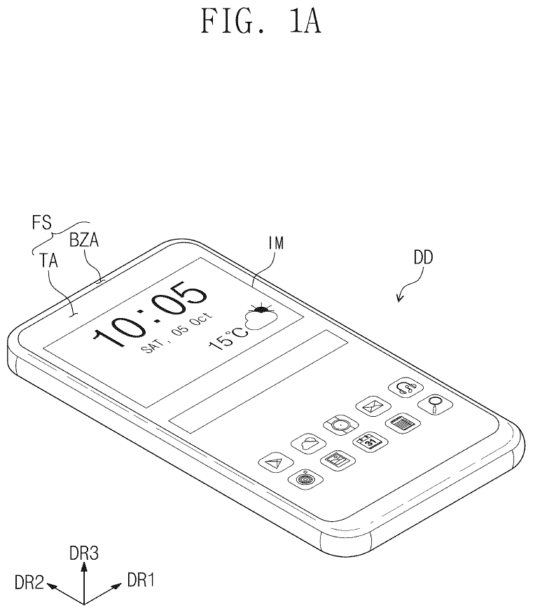

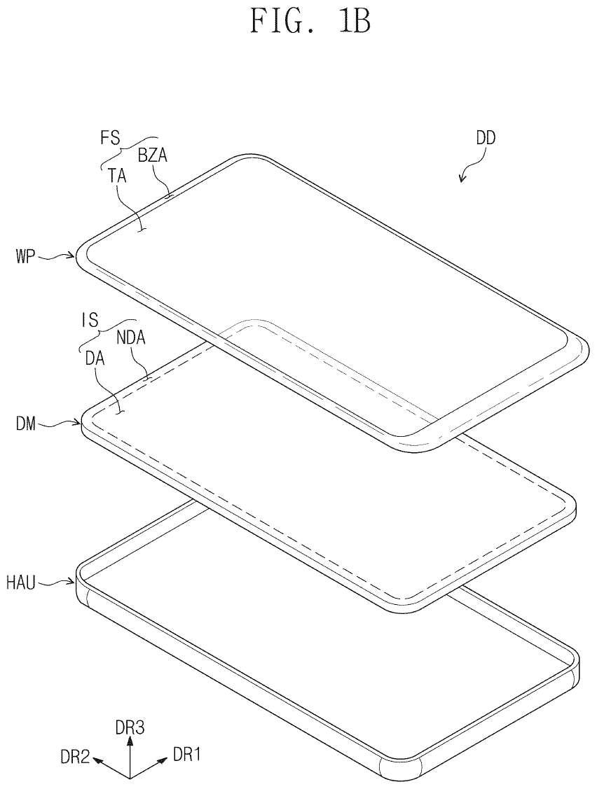

FIG. 1A is a perspective view of a display device DD according to one or more embodiments of the present disclosure, and FIG. 1B is an exploded perspective view of the display device DD according to one or more embodiments of the present disclosure.

The display device DD may be applied to a large-sized electronic item, such as a television set, a monitor, or an outdoor billboard. In addition, the display device DD may be applied to a small- and medium-sized electronic item, such as a personal computer, a notebook computer, a personal digital assistant, a car navigation unit, a game unit, a smartphone, a tablet computer, and a camera. However, these are merely examples, and the display device DD may be employed in other display devices as long as they do not deviate from the concept of the present disclosure. FIGS. 1A and 1B show the smartphone as a representative example of the display device DD.

Referring to FIGS. 1A and 1B, the display device DD may display an image IM through a display surface FS, which is substantially parallel to each of a first direction DR1 and a second direction DR2, toward a third direction DR3. The image IM may include a video as well as a still image. FIG. 1A shows a clock widget and application icons as an example of the image IM. The display surface FS through which the image IM is displayed may correspond to a front surface of the display device DD.

Front (or upper) and rear (or lower) surfaces of each member of the display device DD may be defined with respect to a direction in which the image IM is displayed. The front and rear surfaces may be opposite to each other in the third direction DR3, and a normal line direction of each of the front and rear surfaces may be substantially parallel to the third direction DR3. Meanwhile, directions indicated by the first, second, and third directions DR1, DR2, and DR3 may be relative to each other, and thus, the directions indicated by the first, second, and third directions DR1, DR2, and DR3 may be changed to other directions. In the following descriptions, the expression “when viewed in a plane” means a state of being viewed in the third direction DR3.

The display device DD may include a window WP, a display module DM, and a housing HAU. The window WP and the housing HAU may be coupled to each other to provide an exterior of the display device DD.

The window WP may include an optically transparent insulating material. For example, the window WP may include a glass or plastic material. A front surface of the window WP may define the display surface FS of the display device DD. The display surface FS may include a transmissive area TA and a bezel area BZA. The transmissive area TA may be an optically transparent area. As an example, the transmissive area TA may be an area having a visible light transmittance of about 90% or more.

The bezel area BZA may be an area having a relatively lower transmittance than that of the transmissive area TA. The bezel area BZA may define a shape of the transmissive area TA. The bezel area BZA may be located adjacent to the transmissive area TA and may surround the transmissive area TA. However, this is merely an example, and the bezel area BZA may be omitted from the window WP. The window WP may include at least one functional layer of an anti-fingerprint layer, a hard coating layer, or an anti-reflective layer and should not be particularly limited.

The display module DM may be located under the window WP. The display module DM may have a configuration that substantially generates the image IM. The image IM generated by the display module DM may be displayed through a display surface IS of the display module DM and may be viewed by a user through the transmissive area TA.

The display module DM may include a display area DA and a non-display area NDA. The display area DA may be activated in response to electrical signals. The non-display area NDA may be adjacent to the display area DA. The non-display area NDA may surround the display area DA (e.g., in plan view). The non-display area NDA may be covered by the bezel area BZA, and may not be viewed from the outside.

The housing HAU may be coupled with the window WP. The housing HAU and the window WP, which are coupled to each other, may provide an inner space (e.g., a predetermined inner space). The display module DM may be accommodated in the inner space.

The housing HAU may include a material with a relatively high rigidity. As an example, the housing HAU may include a glass, plastic, or metal material or a plurality of frames and/or plates of combinations thereof. The housing HAU may stably protect the components of the display device DD accommodated in the inner space from external impacts.

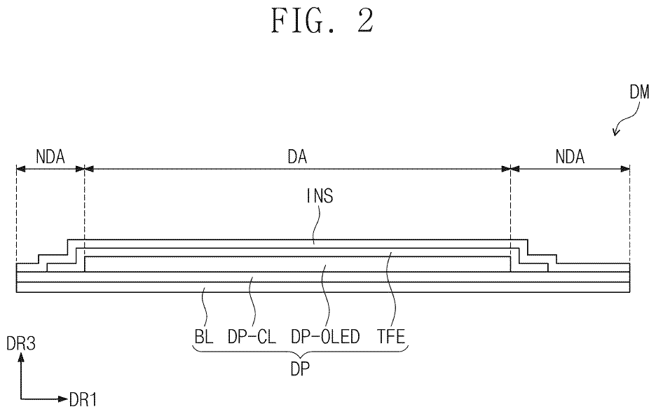

FIG. 2 is a cross-sectional view of the display module DM according to one or more embodiments of the present disclosure.

Referring to FIG. 2, the display module DM may include a display panel DP and an input sensor INS. In one or more embodiments, the display device DD (refer to FIG. 1A) may further include a protective member located on/below a lower surface of the display panel DP, or an anti-reflective member and/or a window member located on/above an upper surface of the input sensor INS.

The display panel DP may be a light-emitting type display panel, however, it should not be particularly limited. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include a quantum dot, a quantum rod, or a micro-LED. The organic light-emitting display panel will be described as the display panel DP.

The display panel DP may include a base layer BL, a circuit element layer DP-CL, a display element layer DP-OLED, and a thin film encapsulation layer TFE. The circuit element layer DP-CL, the display element layer DP-OLED, and the thin film encapsulation layer TFE may be located on the base layer BL. The input sensor INS may be located directly on the thin film encapsulation layer TFE. In the present 1 disclosure, the expression “a component A is located directly on a component B” means that no adhesive layers are present between the component B and the component A.

The base layer BL may include at least one plastic film. The base layer BL may be a flexible substrate and may include a plastic substrate, a glass substrate, a metal substrate, or an organic/inorganic composite material substrate. The display area DA and the non-display area NDA described with reference to FIG. 1B may also be defined in the base layer BL.

The circuit element layer DP-CL may include at least one insulating layer and a circuit element. The insulating layer may include at least one inorganic layer and at least one organic layer. The circuit element may include signal lines and a pixel driving circuit.

The display element layer DP-OLED may include a barrier wall and a light-emitting element. The light-emitting element may include an anode, an intermediate layer, and a cathode.

The thin film encapsulation layer TFE may include a plurality of thin layers. Some thin layers may be located to improve an optical efficiency, and some thin layers may be located to protect organic light-emitting diodes.

The input sensor INS may obtain coordinate information of an external input. The input sensor INS may have a multi-layer structure. The input sensor INS may include a conductive layer having a single-layer or multi-layer structure. The input sensor INS may include an insulating layer having a single-layer or multi-layer structure. The input sensor INS may sense the external input by a capacitive method. However, the present disclosure should not be limited thereto or thereby. As an example, the input sensor INS may sense the external input by an electromagnetic induction method or a pressure-sensing method. Meanwhile, according to one or more embodiments, the input sensor INS may be omitted.

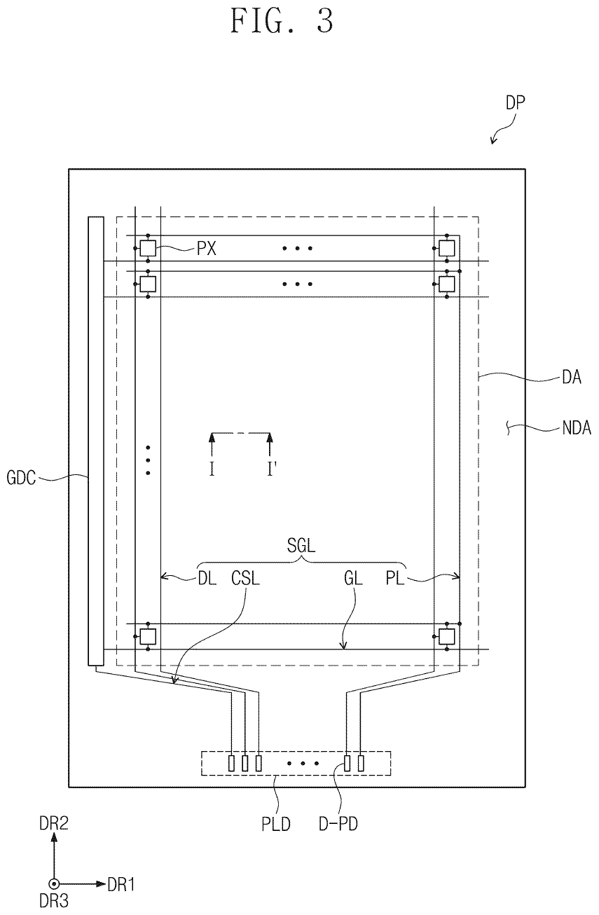

FIG. 3 is a plan view of the display panel DP according to one or more embodiments of the present disclosure.

Referring to FIG. 3, the display panel DP may include the display area DA, and the non-display area NDA around the display area DA. The display panel DP may include pixels PX and signal lines SGL electrically connected to the pixels PX. The display panel DP may include a driving circuit GDC and a pad part PLD. The display area DA and the non-display area NDA may be distinguished from each other by a presence or absence of the pixels PX. The pixels PX may be located in the display area DA. The driving circuit GDC and the pad part PLD may be located in the non-display area NDA.

The pixels PX may be arranged in the first direction DR1 and the second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC, and may provide control signals to the driving circuit GDC.

The driving circuit GDC may include a gate driving circuit. The gate driving circuit may generate a plurality of gate signals, and may sequentially output the gate signals to the gate lines GL. The gate driving circuit may further output other control signals to the pixel driving circuit.

The pad part PLD may be connected to a flexible circuit board. The pad part PLD may include pixel pads D-PD, and the pixel pads D-PD may be pads to connect the flexible circuit board to the display panel DP. Each of the pixel pads D-PD may be connected to a corresponding signal line among the signal lines SGL. The pixel pads D-PD may be connected to corresponding pixels PX via the signal lines SGL. In addition, the driving circuit GDC may be connected to one pixel pad among the pixel pads D-PD.

In addition, the pad part PLD may further include input pads. The input pads may be pads to connect the flexible circuit board to the input sensor INS (refer to FIG. 2). However, the present disclosure should not be limited thereto or thereby. According to one or more embodiments, the input pads may be located in the input sensor INS (refer to FIG. 2), and may be connected to a different circuit board from a circuit board to which the pixel pads D-PD are connected. According to one or more embodiments, the input sensor INS (refer to FIG. 2) may be omitted, and the pad part PLD may not further include the input pads.

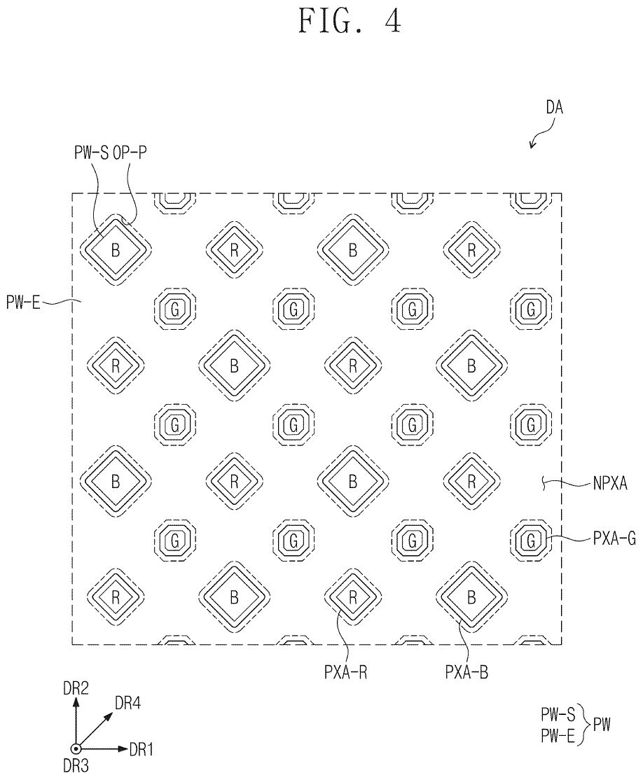

FIG. 4 is an enlarged plan view of a portion of the display area DA (refer to FIG. 2) of the display panel DP (refer to FIG. 2) according to one or more embodiments of the present disclosure. FIG. 4 is a plan view showing the display module DM when viewed from an upper side of the display surface IS (refer to FIG. 1B) of the display module DM (refer to FIG. 1B), and shows an arrangement of light-emitting areas PXA-R, PXA-G, and PXA-B and a barrier wall PW.

Referring to FIG. 4, the display area DA may include first, second, and third light-emitting areas PXA-R, PXA-G, and PXA-B and a peripheral area NPXA surrounding the first, second, and third light-emitting areas PXA-R, PXA-G, and PXA-B. The first, second, and third light-emitting areas PXA-R, PXA-G, and PXA-B may respectively correspond to areas from which lights provided from light-emitting elements are emitted. The first, second, and third light-emitting areas PXA-R, PXA-G, and PXA-B may be distinguished from each other by colors of the lights emitted outward from the display module DM (refer to FIG. 2).

The first, second, and third light-emitting areas PXA-R, PXA-G, and PXA-B may respectively provide first, second, and third color lights having colors different from each other. As an example, the first color light may be a red light, the second color light may be a green light, and the third color light may be a blue light. However, the first, second, and third color lights should not be limited thereto or thereby.

Each of the first, second, and third light-emitting areas PXA-R, PXA-G, and PXA-B may be defined as an area through which an upper surface of the anode is exposed by a light-emitting opening described later. The peripheral area NPXA may define a boundary between the first, second, and third light-emitting areas PXA-R, PXA-G, and PXA-B and may reduce or prevent mixture of the colors of the lights between the first, second, and third light-emitting areas PXA-R, PXA-G, and PXA-B.

Each of the first, second, and third light-emitting areas PXA-R, PXA-G, and PXA-B may be provided in plural and may be repeatedly arranged in an arrangement (e.g., a predetermined arrangement) within the display area DA. As an example, the first and third light-emitting areas PXA-R and PXA-B may be alternately arranged with each other in the first direction DR1 to form a first group. The second light-emitting areas PXA-G may be arranged in the first direction DR1 to form a second group. Each of the first group and the second group may be provided in plural, and the first groups may be alternately arranged with the second groups in the second direction DR2.

One second light-emitting area PXA-G may be located spaced apart from one first light-emitting area PXA-R or one third light-emitting area PXA-B in a fourth direction DR4. The fourth direction DR4 may correspond to a direction between the first and second directions DR1 and DR2.

Meanwhile, FIG. 4 shows an example of the arrangement of the first, second, and third light-emitting areas PXA-R, PXA-G, and PXA-B. However, the arrangement of the first, second, and third light-emitting areas PXA-R, PXA-G, and PXA-B may be changed in various ways and should not be particularly limited. The first, second, and third light-emitting areas PXA-R, PXA-G, and PXA-B may be arranged in a pattern (e.g., a PENTILE™ type pattern, PENTILE™ being a registered trademark of Samsung Display Co., Ltd., Republic of Korea) as shown in FIG. 4. According to one or more embodiments, the first, second, and third light-emitting areas PXA-R, PXA-G, and PXA-B may be arranged in a stripe pattern or a diamond pattern (e.g., a Diamond Pixel™ type pattern, Diamond Pixel™ being a registered trademark of Samsung Display Co., Ltd., Republic of Korea).

Each of the first, second, and third light-emitting areas PXA-R, PXA-G, and PXA-B may have a variety of shapes when viewed in a plane. As an example, each of the first, second, and third light-emitting areas PXA-R, PXA-G, and PXA-B may have a polygonal shape, a circular shape, or an oval shape. In FIG. 4, the first and third light-emitting areas PXA-R and PXA-B each having a quadrangular shape or a lozenge shape, and the second light-emitting area PXA-G having an octagonal shape, are shown as an example.

The first, second, and third light-emitting areas PXA-R, PXA-G, and PXA-B may have substantially the same shape as each other when viewed in the plane, or at least one of the first, second, or third light-emitting areas PXA-R, PXA-G, or PXA-B may have a shape different from the others. FIG. 4 shows a structure in which the first and third light-emitting areas PXA-R and PXA-B have the same shape as each other when viewed in the plane, and in which the second light-emitting area PXA-G has the shape different from those of the first and third light-emitting areas PXA-R and PXA-B as an example.

At least one of the first, second, or third light-emitting areas PXA-R, PXA-G, or PXA-B may have a size that is different from those of the others when viewed in the plane. The size of the first light-emitting area PXA-R emitting the red light may be greater than the size of the second light-emitting area PXA-G emitting the green light, and may be smaller than the size of the third light-emitting area PXA-B emitting the blue light. However, a size relationship between the first, second, and third light-emitting areas PXA-R, PXA-G, and PXA-B according to the colors of the emitted lights should not be limited thereto or thereby and may be changed in various ways depending on a design of the display module DM (refer to FIG. 2). In addition, according to one or more embodiments, the first, second, and third light-emitting areas PXA-R, PXA-G, and PXA-B may have substantially the same size as each other when viewed in the plane.

Meanwhile, the shape, size, and arrangement of the first, second, and third light-emitting areas PXA-R, PXA-G, and PXA-B of the display module DM (refer to FIG. 2) may be designed in various ways depending on the colors of the emitted lights, the size of the display module DM (refer to FIG. 2), and the configuration of the display module DM (refer to FIG. 2), and they should not be limited to the one or more embodiments corresponding to FIG. 4.

The barrier wall PW may include a first barrier wall PW-S and a second barrier wall PW-E. The first barrier wall PW-S may overlap the first, second, and third light-emitting areas PXA-R, PXA-G, and PXA-B, and the second barrier wall PW-E may surround the first, second, and third light-emitting areas PXA-R, PXA-G, and PXA-B. An inner side surface of the second barrier wall PW-E may define a barrier wall opening OP-P. The first barrier wall PW-S may be located in the barrier wall opening OP-P. That is, the second barrier wall PW-E may surround the first barrier wall PW-S, and the first barrier wall PW-S may be spaced apart from the second barrier wall PW-E when viewed in the plane.

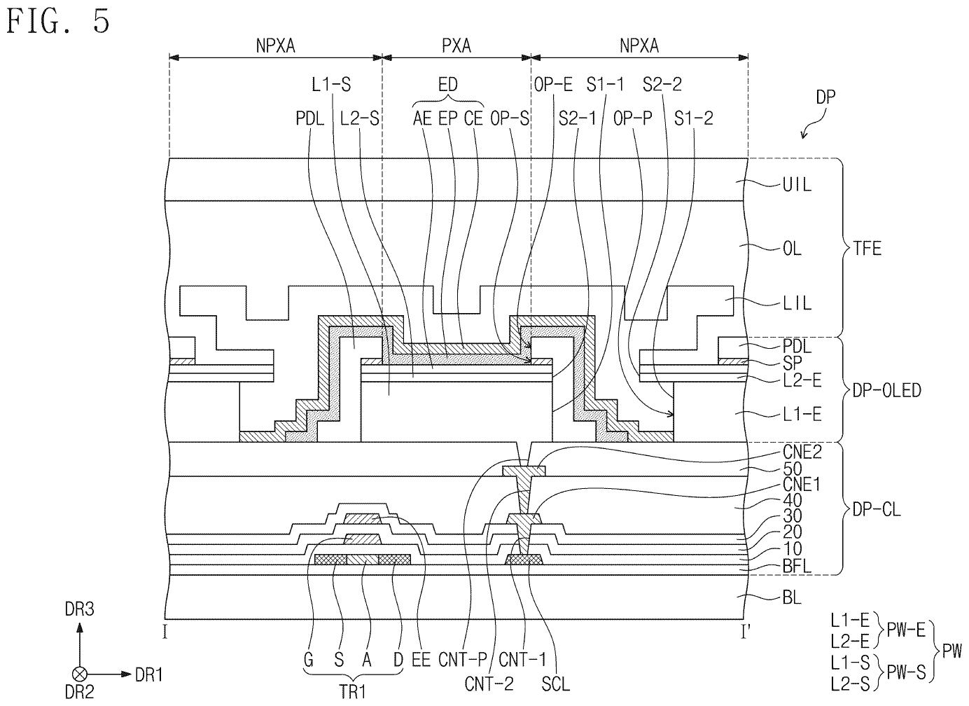

FIG. 5 is a cross-sectional view taken along the line I-I′ of FIG. 3. In FIG. 5, the same reference numerals denote the same elements in FIG. 2, and thus, detailed descriptions of the same elements will be omitted. FIG. 5 is an enlarged view illustrating a light-emitting area PXA of the display area DA (refer to FIG. 4), and the light-emitting area PXA of FIG. 5 may correspond to one of the first, second, and third light-emitting areas PXA-R, PXA-G, and PXA-B of FIG. 4.

Referring to FIG. 5, the display panel DP may include the base layer BL, the circuit element layer DP-CL, the display element layer DP-OLED, and the thin film encapsulation layer TFE.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by a photolithography process and an etching process. The semiconductor pattern, the conductive pattern, and the signal line, which are included in the circuit element layer DP-CL and the display element layer DP-OLED, may be formed through the above processes.

The circuit element layer DP-CL may be located on the base layer BL. The circuit element layer DP-CL may include a buffer layer BFL, a transistor TR1, a signal transmission area SCL, first, second, third, fourth, and fifth insulating layers 10, 20, 30, 40, and 50, an electrode EE, and a plurality of connection electrodes CNE1 and CNE2.

The buffer layer BFL may be located on the base layer BL. The buffer layer BFL may increase an adhesive force between the base layer BL and the semiconductor pattern. The buffer layer BFL may include a silicon oxide layer and a silicon nitride layer, and the silicon oxide layer and the silicon nitride layer may be alternately stacked with each other.

The semiconductor pattern may be located on the buffer layer BFL. The semiconductor pattern may include polysilicon, although it should not be limited thereto or thereby. The semiconductor pattern may include an amorphous silicon or metal oxide. FIG. 5 shows a portion of the semiconductor pattern, and the semiconductor pattern may be further located in the light-emitting areas PXA-R, PXA-G, and PXA-B (refer to FIG. 4). The semiconductor pattern may be arranged with a specific rule over the light-emitting areas PXA-R, PXA-G, and PXA-B. The semiconductor pattern may have different electrical properties depending on whether it is doped or not. The semiconductor pattern may include a first region having a relatively high doping concentration and a second region having a relatively low doping concentration. The first region may be doped with an N-type dopant or a P-type dopant. A P-type transistor may include the first region doped with the P-type dopant.

The first region may have a conductivity that is greater than that of the second region, and may substantially serve as an electrode or a signal line. The second region may substantially correspond to an active (or a channel) of the transistor. In other words, a portion of the semiconductor pattern may be the active of the transistor, another portion of the semiconductor pattern may be a source or a drain of the transistor, and another or remaining portion of the semiconductor pattern may be a conductive area.

A source S, an active A, and a drain D of the transistor TR1 may be formed from the semiconductor pattern. FIG. 5 shows a portion of the signal transmission area SCL formed from the semiconductor pattern. In one or more embodiments, the signal transmission area SCL may be connected to the drain D of the transistor TR1 in a plane.

The first, second, third, fourth, and fifth insulating layers 10, 20, 30, 40, and 50 may be located on the buffer layer BFL. Each of the first to fifth insulating layers 10, 20, 30, 40, and 50 may be an inorganic layer or an organic layer.

The first insulating layer 10 may be located on the buffer layer BFL. The first insulating layer 10 may cover the source S, the active A, and the drain D of the transistor TR1 and the signal transmission area SCL. A gate G of the transistor TR1 may be located on the first insulating layer 10. The second insulating layer 20 may be located on the first insulating layer 10, and may cover the gate G. The electrode EE may be located on the second insulating layer 20. The third insulating layer 30 may be located on the second insulating layer 20, and may cover the electrode EE.

A first connection electrode CNE1 may be located on the third insulating layer 30. The first connection electrode CNE1 may be connected to the signal transmission area SCL via a contact hole CNT-1 defined through the first, second, and third insulating layers 10, 20, and 30. The fourth insulating layer 40 may be located on the third insulating layer 30, and may cover the first connection electrode CNE1. The fourth insulating layer 40 may be an organic layer.

A second connection electrode CNE2 may be located on the fourth insulating layer 40. The second connection electrode CNE2 may be connected to the first connection electrode CNE1 via a contact hole CNT-2 defined through the fourth insulating layer 40. The fifth insulating layer 50 may be located on the fourth insulating layer 40 and may cover the second connection electrode CNE2. The fifth insulating layer 50 may be an organic layer.

The display element layer DP-OLED may be located on the circuit element layer DP-CL. The display element layer DP-OLED may include the barrier wall PW, a sacrificial pattern SP, a pixel definition layer PDL, and the light-emitting element ED.

The barrier wall PW may be located on the circuit element layer DP-CL. The barrier wall PW may include the first barrier wall PW-S and the second barrier wall PW-E. The first barrier wall PW-S may overlap the light-emitting opening OP-E when viewed in the plane, and the second barrier wall PW-E may surround the light-emitting opening OP-E when viewed in the plane. That is, the second barrier wall PW-E may surround the first barrier wall PW-S, and the first barrier wall PW-S may be spaced apart from the second barrier wall PW-E when viewed in the plane. The barrier wall PW may be provided with the barrier wall opening OP-P defined therethrough. In detail, the barrier wall opening OP-P may be defined by the inner side surfaces of the second barrier wall PW-E. The barrier wall opening OP-P may correspond to, or may overlap, the light-emitting opening OP-E.

The barrier wall PW may include a plurality of layers sequentially stacked. The first barrier wall PW-S may include first and second barrier wall layers L1-S and L2-S, and the second barrier wall PW-E may include first and second barrier wall layers L1-E and L2-E. The first barrier wall layers L1-S and L1-E may be located above the base layer BL. In detail, the first barrier wall layers L1-S and L1-E may be located on the fifth insulating layer 50 of the circuit element layer DP-CL. The second barrier wall layers L2-S and L2-E may be located on the first barrier wall layers L1-S and L1-E, respectively. As shown in FIG. 5, the first barrier wall layers L1-S and L1-E may have a thickness that is greater than a thickness of the second barrier wall layers L2-S and L2-E. However, the present disclosure should not be limited thereto or thereby.

Each of the first barrier wall PW-S and the second barrier wall PW-E may include a conductive material. That is, each of the first barrier wall layers L1-S and L1-E and the second barrier wall layers L2-S and L2-E may include the conductive material. As an example, the conductive material may include a metal, a transparent conductive oxide (TCO), or combinations thereof. As an example, the metal may include gold (Au), silver (Ag), aluminum (AI), magnesium (Mg), lithium (Li), molybdenum (Mo), titanium (Ti), copper (Cu), or alloys. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Inner side surfaces S1-1 and S2-1 of the first barrier wall PW-S may be aligned with each other when viewed in a cross-section. The inner side surface S1-1 of the first barrier wall layer L1-S of the first barrier wall PW-S may be aligned with the inner side surface S2-1 of the second barrier wall layer L2-S of the first barrier wall PW-S.

The second barrier wall PW-E may have an undercut shape when viewed in the cross-section. At least one layer of a plurality of layers of the second barrier wall PW-E may be recessed more than the other layers, and thus, the second barrier wall PW-E may have a tip portion. As an example, the first barrier wall layer L1-E of the second barrier wall PW-E may have an undercut shape with respect to the second barrier wall layer L2-E of the second barrier wall PW-E. The second barrier wall layer L2-E of the second barrier wall PW-E, which protrudes more than the first barrier wall layer L1-E of the second barrier wall PW-E toward the light-emitting opening OP-E, may form the tip portion. A portion of the second barrier wall layer L2-E, which protrudes toward the light-emitting area PXA, may be defined as the tip portion in the barrier wall PW. That is, the inner side surface S2-2 of the second barrier wall layer L2-E of the second barrier wall PW-E may be closer to a center of the anode AE than the inner side surface S1-2 of the first barrier wall layer L1-E of the second barrier wall PW-E.

The light-emitting element ED may include the anode AE (or a first electrode), a light-emitting pattern EP, and the cathode CE (or a second electrode). The light-emitting element ED may be located in the barrier wall opening OP-P.

The anode AE may be located on the first barrier wall PW-S. The anode AE may be a transmissive electrode, a semi-transmissive electrode, or a reflective electrode. The anode AE may have a single-layer or multi-layer structure. The anode AE may include a layer containing indium tin oxide (ITO) and a layer containing silver (Ag). As an example, the anode AE may include a layer (hereinafter, referred to as a lower ITO layer) containing indium tin oxide (ITO), a layer (hereinafter, referred to as an Ag layer) located on the lower ITO layer and containing silver (Ag), and a layer (hereinafter, referred to as an upper ITO layer) located on the Ag layer and containing indium tin oxide (ITO).

The first barrier wall PW-S may be connected to the second connection electrode CNE2 via a barrier wall contact hole CNT-P defined through the fifth insulating layer 50. Accordingly, the anode AE formed on the first barrier wall PW-S may be electrically connected to the signal transmission area SCL through the first and second connection electrodes CNE1 and CNE2 and the first barrier wall PW-S, and may be electrically connected to a corresponding circuit element.

The sacrificial pattern SP may be located on the anode AE. The sacrificial pattern SP may be located between the anode AE and the pixel definition layer PDL when viewed in the cross-section. A sacrificial opening OP-S may be defined through the sacrificial pattern SP, and a portion of an upper surface of the anode AE may be exposed through the sacrificial opening OP-S. The sacrificial opening OP-S may overlap the light-emitting opening OP-E described later.

The sacrificial pattern SP may include a transparent conductive oxide. As an example, the sacrificial pattern SP may include indium tin oxide (ITO), indium zinc oxide (IZO), zinc oxide, indium oxide, indium gallium oxide, indium gallium zinc oxide (IGZO), aluminum zinc oxide, or zinc indium tin oxide (ZITO). The sacrificial pattern SP may include indium gallium zinc oxide (IGZO).

The pixel definition layer PDL may be located above the base layer BL. As an example, the pixel definition layer PDL may be located on the barrier wall PW and the circuit element layer DP-CL. A portion of the pixel definition layer PDL may be located on the first barrier wall PW-S and the circuit element layer DP-CL, and the other portion of the pixel definition layer PDL may be located on the second barrier wall PW-E.

The pixel definition layer PDL may be provided with the light-emitting opening OP-E. As an example, the portion of the pixel definition layer PDL, which is located on the first barrier wall PW-S, may define the light-emitting opening OP-E. The portion of the pixel definition layer PDL, which defines the light-emitting opening OP-E, may be located in the barrier wall opening OP-P. The light-emitting opening OP-E may correspond to the anode AE, and at least a portion of the anode AE may be exposed through the light-emitting opening OP-E of the pixel definition layer PDL.

In addition, the light-emitting opening OP-E may correspond to the sacrificial opening OP-S of the sacrificial pattern SP. The upper surface of the anode AE may be spaced apart from the pixel definition layer PDL with the sacrificial pattern SP interposed therebetween when viewed in the cross-section, and thus, damage to the anode AE may be reduced or prevented during a process of forming the light-emitting opening OP-E.

When viewed in the plane, an inner side surface of the sacrificial pattern SP provided with the sacrificial opening OP-S may be substantially aligned with an inner side surface of the pixel definition layer PDL provided with the light-emitting opening OP-E. In this case, the light-emitting area PXA may be an area of the anode AE exposed through the corresponding sacrificial opening OP-S, although it should not be limited thereto or thereby. The light-emitting opening OP-E may have a size that is smaller than a size of the sacrificial opening OP-S. That is, the inner side surface of the pixel definition layer PDL provided with the light-emitting opening OP-E may be closer to the center of the anode AE than the inner side surface of the sacrificial pattern SP provided with the sacrificial opening OP-S is.

The pixel definition layer PDL may include an inorganic insulating material. As an example, the pixel definition layer PDL may include silicon nitride (SiNₓ). The pixel definition layer PDL may be located between the anode AE and the barrier wall PW, and may reduce or prevent the likelihood of the anode AE from being electrically connected to the barrier wall PW. In addition, the pixel definition layer PDL may protect the anode AE and the sacrificial pattern SP during processes of forming the light-emitting opening OP-E and the sacrificial opening OP-S. This will be described in detail later.

The light-emitting pattern EP may be located on the anode AE. In detail, the light-emitting pattern EP may be located on the anode AE and the pixel definition layer PDL. The light-emitting pattern EP may include the light-emitting layer containing a light-emitting material. The light-emitting pattern EP may further include a hole injection layer and a hole transport layer, which are located between the anode AE and the light-emitting layer, and an electron transport layer and an electron injection layer, which are located on the light-emitting layer. The light-emitting pattern EP may be referred to as an organic layer or an intermediate layer.

The light-emitting pattern EP may be patterned by the tip portion defined by the second barrier wall PW-E. The light-emitting pattern EP may be located in the sacrificial opening OP-S, the light-emitting opening OP-E, and the barrier wall opening OP-P. The light-emitting pattern EP may cover the anode AE, a portion of the pixel definition layer PDL, and a portion of an upper surface of the fifth insulating layer 50, which is exposed through the barrier wall opening OP-P.

The cathode CE may be located on the light-emitting pattern EP, and may cover the light-emitting pattern EP. The cathode CE may be patterned by the tip portion defined by the second barrier wall PW-E. At least a portion of the cathode CE may be located in the barrier wall opening OP-P, and may be in contact with the second barrier wall PW-E in the barrier wall opening OP-P. As an example, the cathode CE may be in contact with the inner side surface S1-2 of the first barrier wall layer L1-E of the second barrier wall PW-E.

The cathode CE may have a conductivity. The cathode CE may be formed of various materials having the conductivity, such as a metal, a transparent conductive oxide (TCO), or a conductive polymer material. As an example, the cathode CE may include silver (Ag), magnesium (Mg), lead (Pb), copper (Cu), or compounds thereof. The second barrier wall PW-E may receive a driving voltage, and thus, the cathode CE may be electrically connected to the second barrier wall PW-E, and may receive the driving voltage.

According to the present disclosure, the light-emitting patterns EP may be patterned in the pixel units by the tip portion defined in the barrier wall PW, and may be deposited. That is, the light-emitting patterns may be commonly formed using an open mask, but may be suitably separated in the unit of pixel by the barrier wall PW.

On the other hand, in a case where the light-emitting patterns EP are patterned using a fine metal mask (FMM), a support spacer protruded from the barrier wall is suitable to support the fine metal mask. In addition, because the fine metal mask is spaced apart from a base surface on which a patterning process is performed 1 by a height of the barrier wall and the spacer, there may be limitations in implementing the high resolution. Further, because the fine metal mask contacts the spacer, a foreign substance may remain on the spacer after the patterning process of the light-emitting patterns EP, or the spacer may be damaged by the fine metal mask. As a result, a defective display panel may be formed.

As the display panel DP includes the barrier wall PW, the light-emitting elements may be suitably physically separated from each other. Accordingly, a leakage current or a driving error between the light-emitting areas PXA-R, PXA-G, and PXA-B (refer to FIG. 4) adjacent to each other may be reduced or prevented, and the light-emitting elements may be driven independently from each other.

For example, because the light-emitting patterns EP are patterned without a mask that contacts components provided inside the display area DA (refer to FIG. 1B), the defect rate of the display panel DP may be reduced, and thus, the display device with improved process reliability may be provided. Even though the support spacer protruded from the barrier wall PW is not provided, the light-emitting patterns EP may be patterned. Therefore, the light-emitting areas PXA-R, PXA-G, and PXA-B may be finely formed in terms of its size, and thus, the display panel DP that is suitable to implement in high resolution may be provided.

In addition, because a large-sized mask is not required when manufacturing a large-sized display panel, the process cost may be reduced, and because the display panel is not affected by the defects occurring due to the large-sized mask, the process reliability of the display panel may be improved.

The thin film encapsulation layer TFE may be located on the display element layer DP-OLED. The thin film encapsulation layer TFE may include a lower encapsulation inorganic pattern LIL, an encapsulation organic layer OL, and an upper encapsulation inorganic layer UIL.

The lower encapsulation inorganic pattern LIL may be located to correspond to the light-emitting opening OP-E. A portion of the lower encapsulation inorganic pattern LIL may be located in the barrier wall opening OP-P, and the other portion of the lower encapsulation inorganic pattern LIL may be located above the barrier wall PW. The portion of the lower encapsulation inorganic pattern LIL, which is located in the barrier wall opening OP-P, may be located on the cathode CE to cover the light-emitting element ED, and may be filled in the barrier wall opening OP-P.

The encapsulation organic layer OL may cover the lower encapsulation inorganic pattern LIL, and may provide a substantially flat upper surface thereon. The upper encapsulation inorganic layer UIL may be located on the encapsulation organic layer OL.

The lower encapsulation inorganic pattern LIL and the upper encapsulation inorganic layer UIL may protect the display element layer DP-OLED from moisture and oxygen, and the encapsulation organic layer OL may protect the display element layer DP-OLED from a foreign substance, such as dust particles.

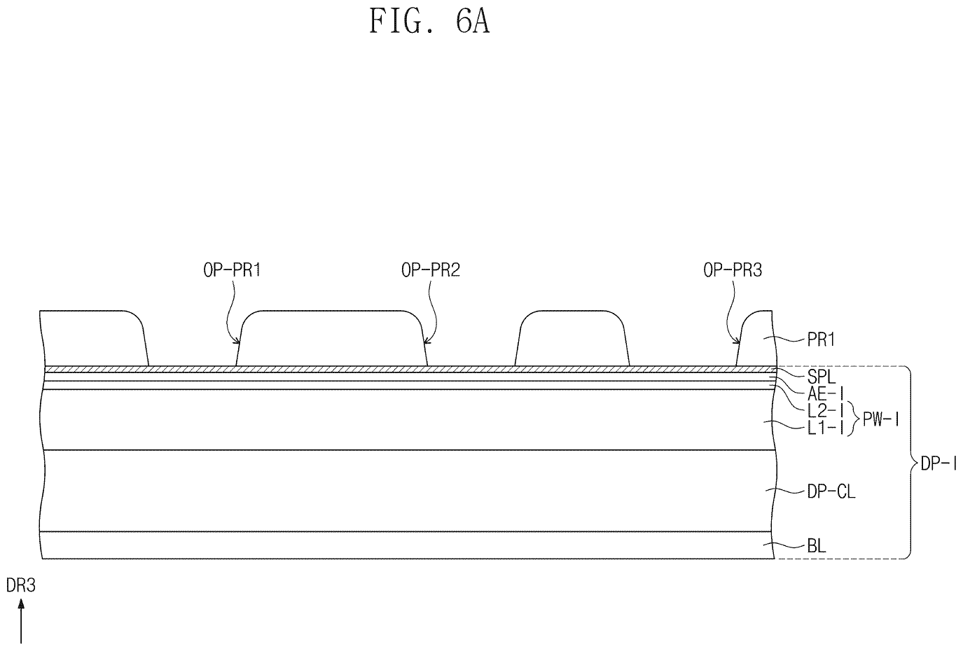

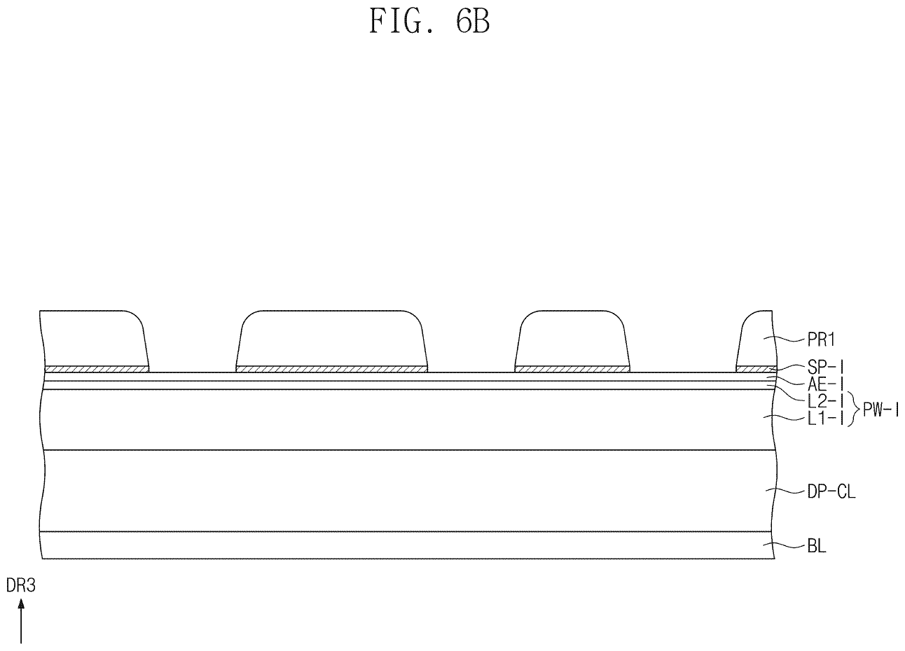

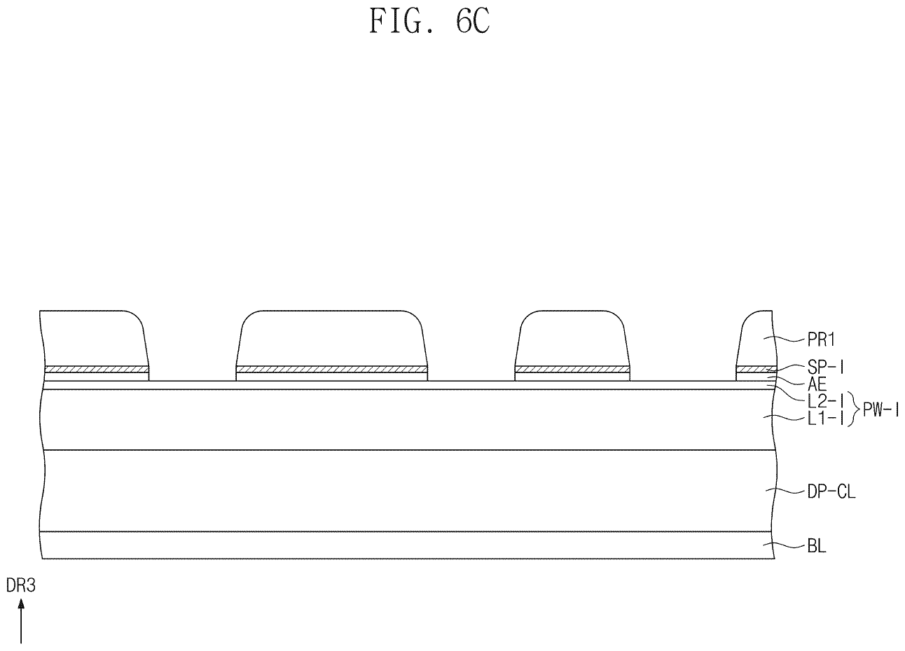

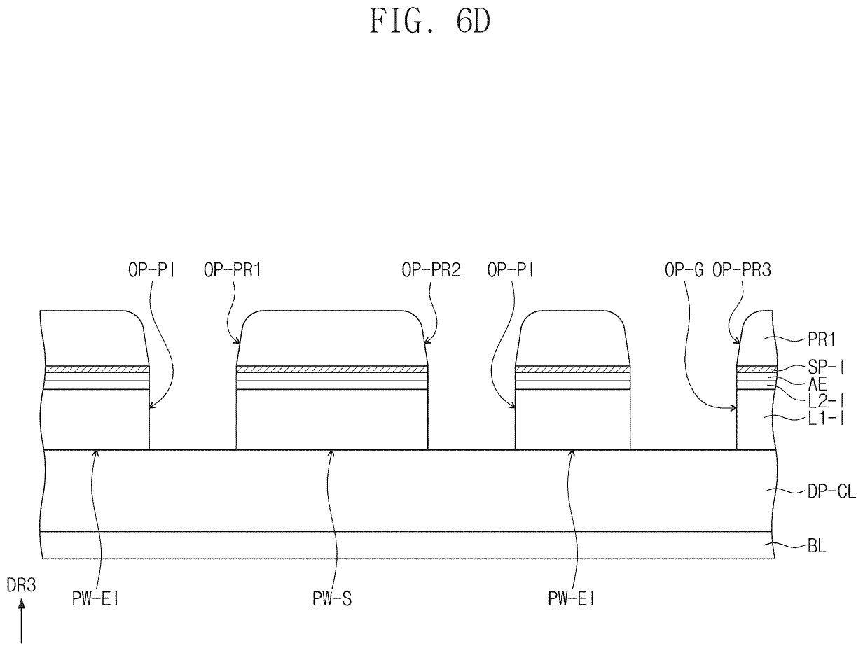

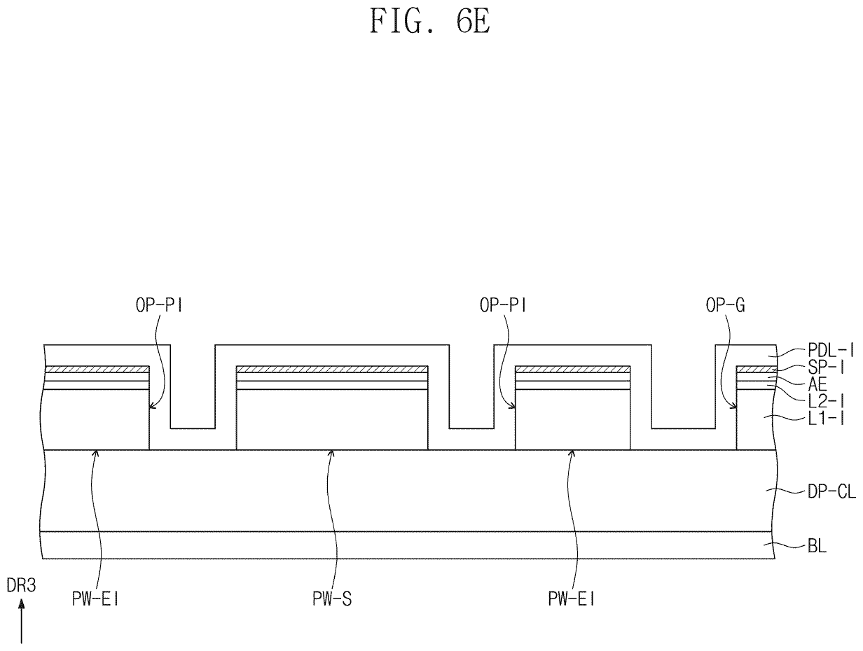

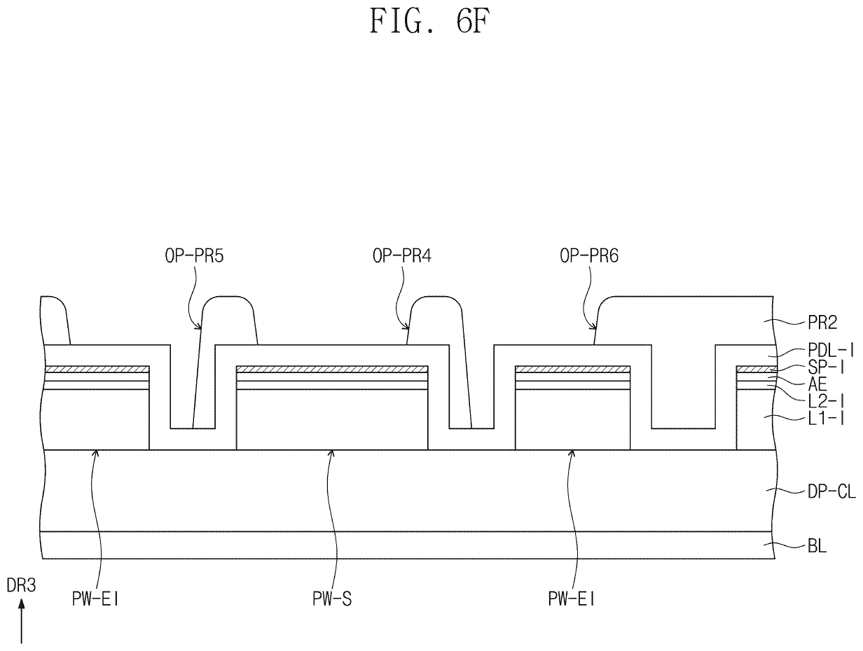

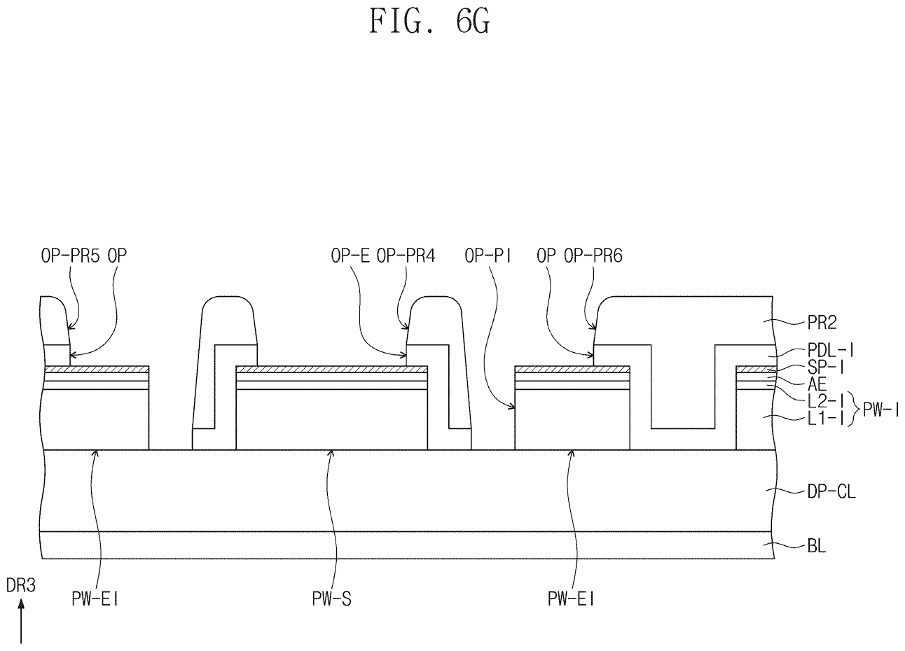

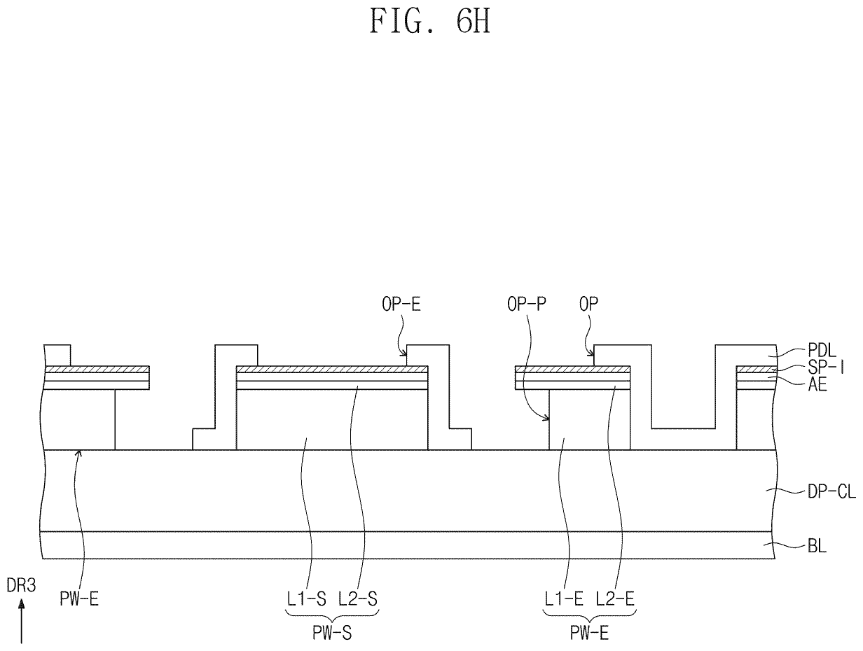

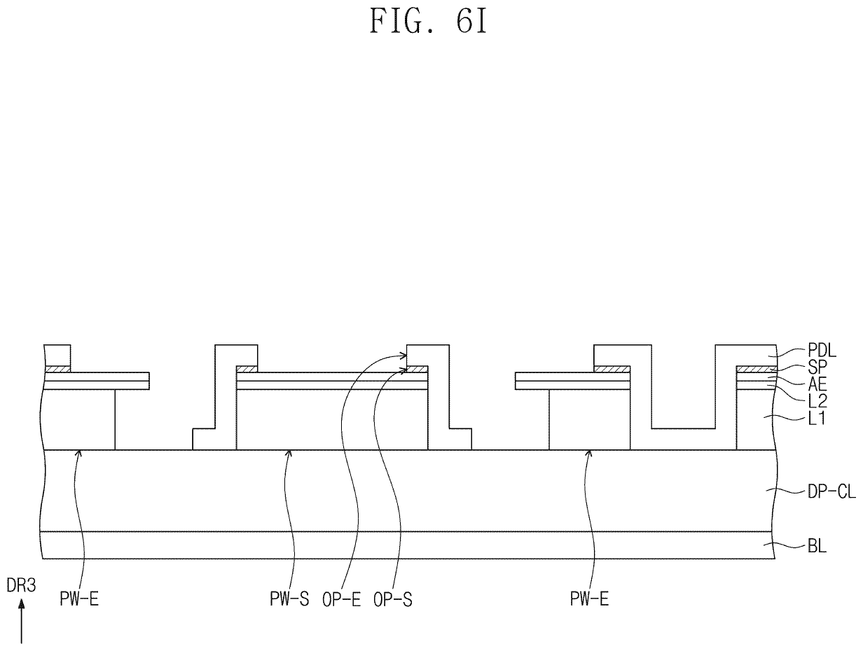

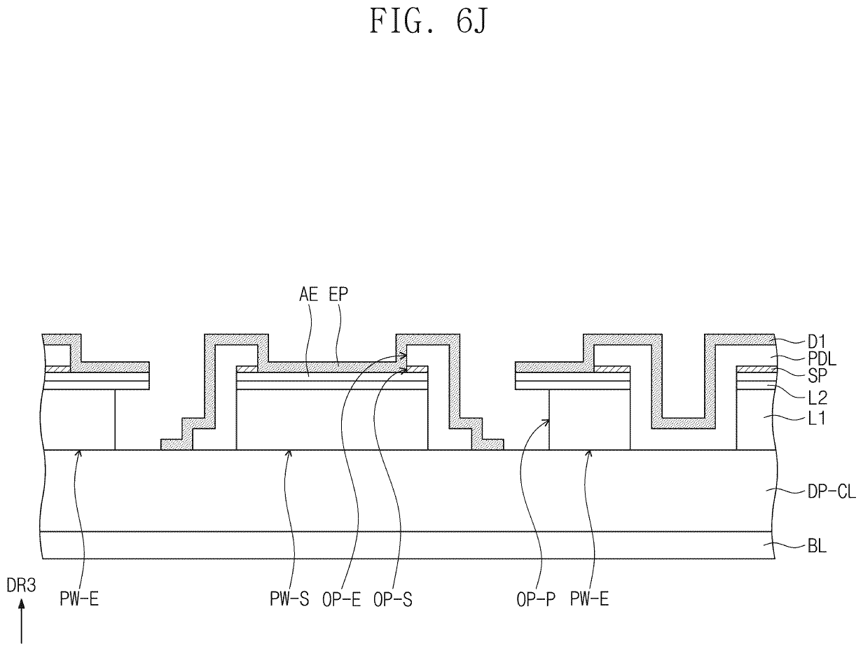

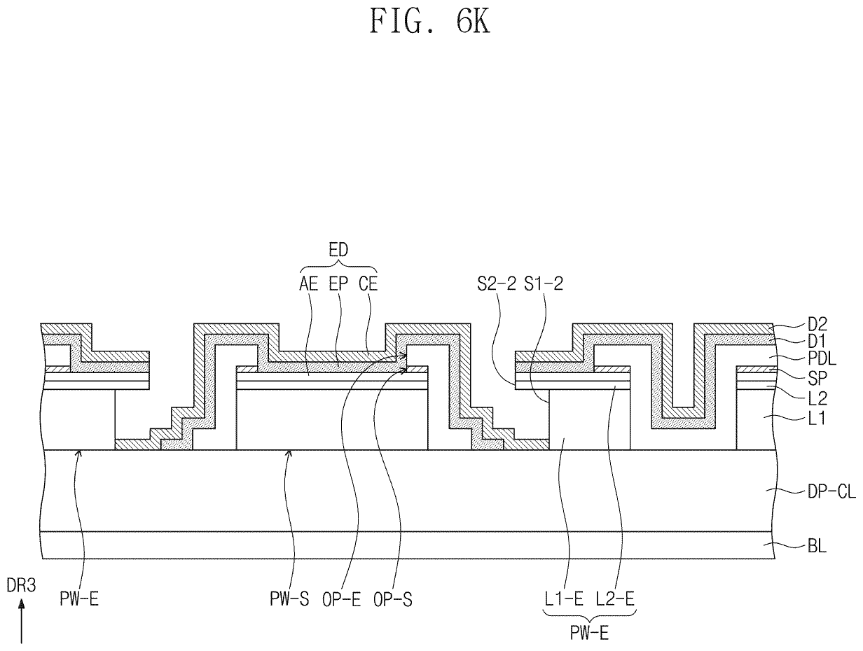

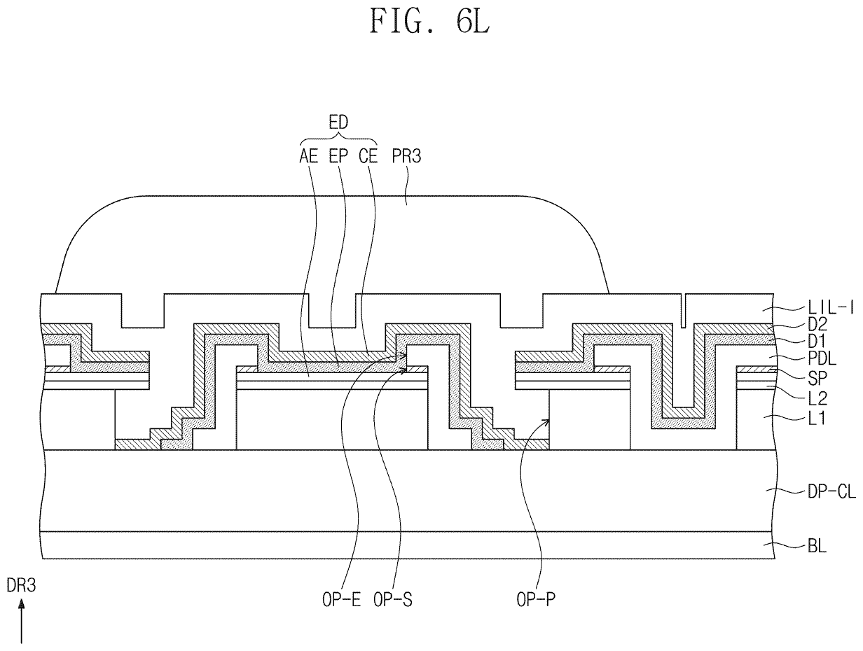

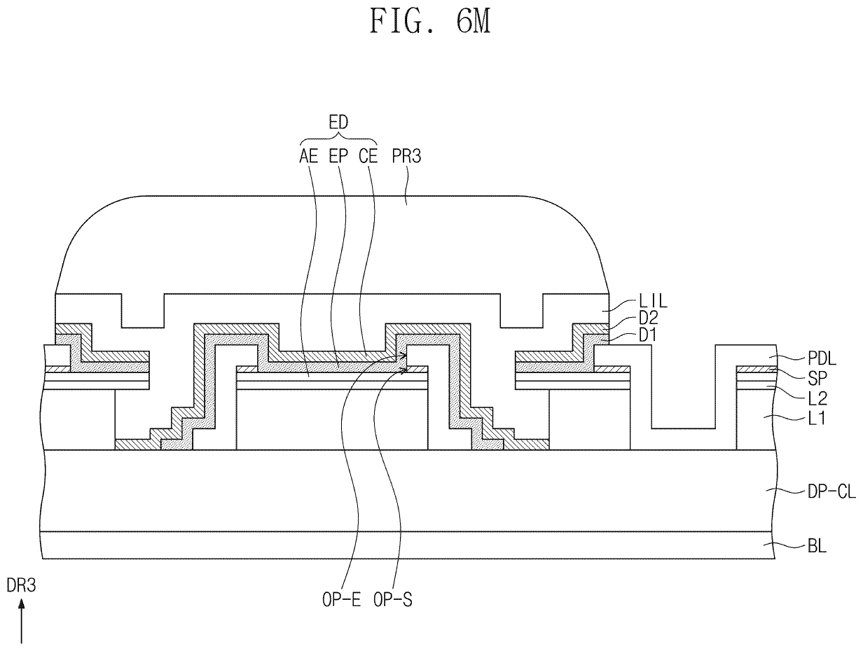

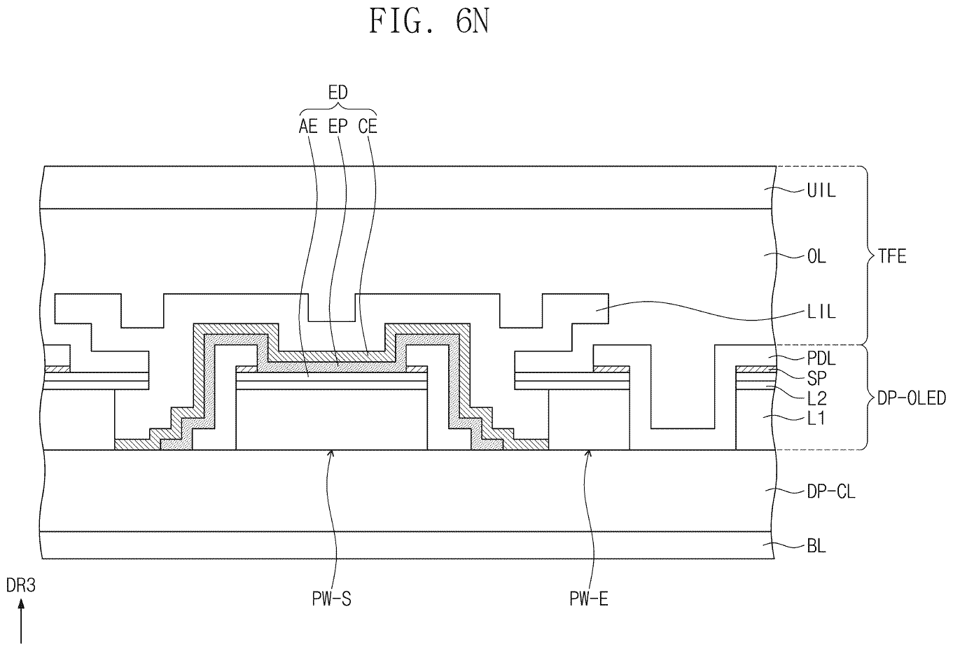

FIGS. 6A to 6N are cross-sectional views illustrating processes of a method of manufacturing the display panel according to one or more embodiments of the present disclosure. In FIGS. 6A to 6N, the same/similar reference numerals denote the same/similar elements described with reference to FIGS. 1 to 5, and thus, detailed descriptions of the same/similar elements will be omitted.

The manufacturing method of the display panel may include providing a preliminary display panel including the base layer, a preliminary barrier wall located on the base layer, an anode layer located on the preliminary barrier wall, and a sacrificial layer, etching the sacrificial layer to form a preliminary sacrificial pattern, etching the anode layer to form the anode, first etching the preliminary barrier wall to form the first barrier wall and a second preliminary barrier wall, depositing a preliminary pixel definition layer on the base layer, etching the preliminary pixel definition layer to form the pixel definition layer through which the light-emitting opening overlapping the first barrier wall and the opening exposing an inner side surface of the second preliminary barrier wall are defined, second etching the preliminary barrier wall to form the second barrier wall through which the barrier wall opening is defined, and forming the light-emitting pattern and the cathode to overlap the barrier wall opening when viewed in the plane.

Hereinafter, a method of forming one light-emitting element ED and the lower encapsulation inorganic pattern LIL, the encapsulation organic layer OL, and the upper encapsulation inorganic layer UIL, which cover the one light-emitting element ED, will be described with reference to FIGS. 6A to 6N. The display panel manufactured through the processes shown in FIGS. 6A to 6N may correspond to the display panel DP of FIG. 5.

Referring to FIG. 6A, the manufacturing method of the display panel may include the providing of the preliminary display panel DP-I. The preliminary display panel DP-I may include the base layer BL, the circuit element layer DP-CL, the preliminary barrier wall PW-I, the anode layer AE-I, and the sacrificial layer SPL.

The circuit element layer DP-CL may be formed through a conventional manufacturing process of the circuit element, which forms the insulating layer, the semiconductor layer, and the conductive layer by the coating or depositing process, and selectively patterns the insulating layer, the semiconductor layer, and the conductive layer using a photolithography and etching processes to form the semiconductor pattern, the conductive pattern, and the signal line.

The preliminary barrier wall PW-I may include a first preliminary barrier wall layer L1-I and a second preliminary barrier wall layer L2-1. The first preliminary barrier wall layer L1-I may be deposited on the circuit element layer DP-CL, and the second preliminary barrier wall layer L2-I may be formed on the first preliminary barrier wall layer L1-1. The first and second preliminary barrier wall layers L1-I and L2-I may be formed of a conductive material through a deposition process. As an example, the first and second preliminary barrier wall layers L1-I and L2-I may include a metal, a transparent conductive oxide (TCO), or combinations thereof.

The anode layer AE-I may be formed on the second preliminary barrier wall layer L2-1. The anode layer AE-I may be a transmissive electrode, a semi-transmissive electrode, or a reflective electrode. The anode layer AE-I may include the layer (hereinafter, referred to as the lower ITO layer) containing indium tin oxide (ITO), the layer (hereinafter, referred to as the Ag layer) located on the lower ITO layer and containing silver (Ag), and the layer (hereinafter, referred to as the upper ITO layer) located on the Ag layer and containing indium tin oxide (ITO).

The sacrificial layer SPL may be formed on the anode layer AE-I. The sacrificial layer SPL may include the transparent conductive oxide. As an example, the sacrificial layer SPL may include an indium gallium zinc oxide (IGZO).

The preliminary barrier wall PW-I, the anode layer AE-I, and the sacrificial layer SPL, which are formed on the circuit element layer DP-CL, may be formed through successive deposition processes.

Then, the manufacturing method of the display panel may include forming a first photoresist layer PR1 on the sacrificial layer SPL. The first photoresist layer PR1 may be formed by forming a preliminary photoresist layer on the sacrificial layer SPL, and patterning the preliminary photoresist layer using a photomask. First, second, and third photo openings OP-PR1, OP-PR2, and OP-PR3 may be formed through the first photoresist layer PR1 through the patterning process. The first and second photo openings OP-PR1 and OP-PR2 may overlap the barrier wall opening OP-P (refer to FIG. 6H), and the third photo opening OP-PR3 may not overlap the barrier wall opening OP-P.

Referring to FIG. 6B, the manufacturing method of the display panel may include the etching of the sacrificial layer SPL (refer to FIG. 6A) to form the preliminary sacrificial pattern SP-I.

The forming of the preliminary sacrificial pattern SP-I may be performed by a wet etching process using the first photoresist layer PR1 as a mask. Portions of the sacrificial layer SPL, which do not overlap the first photoresist layer PR1, may be etched and removed, and portions of the sacrificial layer SPL, which remain without being etched, may be used as the preliminary sacrificial pattern SP-I.

Referring to FIG. 6C, the manufacturing method of the display panel may include the etching of the anode layer AE-I (refer to FIG. 6B) to form the anode AE.

The forming of the anode AE may be performed by a wet etching process using the first photoresist layer PR1 as a mask. Portions of the anode layer AE-I, which do not overlap the first photoresist layer PR1, may be etched and removed, and portions of the anode layer AE-I, which remain without being etched, may be used as the anode AE.

Referring to FIG. 6D, the manufacturing method of the display panel may include the first etching of the preliminary barrier wall PW-I (refer to FIG. 6C) to form the first barrier wall PW-S and the second preliminary barrier wall PW-El.

The forming of the first barrier wall PW-S and the second preliminary barrier wall PW-EI may be performed by a dry etching process using the first photoresist layer PR1 as a mask. Portions of the preliminary barrier wall PW-I, which do not overlap the first photoresist layer PR1, may be etched and removed, and portions of the preliminary barrier wall PW-I, which remain without being etched, may be used as the first barrier wall PW-S or the second preliminary barrier wall PW-El.

As an example, a preliminary barrier wall opening OP-PI may be formed in an area where the portions of the preliminary barrier wall PW-I, which overlap the first and second photo openings OP-PR1 and OP-PR2, are removed, and an outgassing opening OP-G may be formed in an area where the portion of the preliminary barrier wall PW-I, which overlaps the third photo opening OP-PR3, are removed. The inner side surfaces of the first preliminary barrier wall layer L1-I and the second preliminary barrier wall layer L2-I of the second preliminary barrier wall PW-EI, through which the preliminary barrier wall opening OP-PI is defined, may be aligned with each other. The outgassing opening OP-G may be an opening through which gases generated from the insulating layers of the circuit element layer DP-CL are discharged. In addition, among the portions of the preliminary barrier wall PW-I that remain without being etched, a portion that defines the preliminary barrier wall opening OP-PI may serve as the second preliminary barrier wall PW-EI, and the first barrier wall PW-S may be formed in the preliminary barrier wall opening OP-PI.

Referring to FIG. 6E, the manufacturing method of the display panel may include removing the first photoresist layer PR1 (refer to FIG. 6D) and depositing the preliminary pixel definition layer PDL-I on the base layer BL.

The preliminary pixel definition layer PDL-I may be deposited on the circuit element layer DP-CL and the preliminary sacrificial pattern SP-I. The preliminary pixel definition layer PDL-I may be deposited in the preliminary barrier wall opening OP-PI and the outgassing opening OP-G. The preliminary pixel definition layer PDL-I may include an inorganic insulating material. As an example, preliminary pixel definition layer PDL-I may include silicon nitride (SiNx).

Referring to FIG. 6F, the manufacturing method of the display panel may include forming a second photoresist layer PR2 on the preliminary pixel definition layer PDL-I. The second photoresist layer PR2 may be formed by forming a preliminary photoresist layer on the preliminary pixel definition layer PDL-I and patterning the preliminary photoresist layer using a photomask. Fourth, fifth, and sixth photo openings OP-PR4, OP-PR5, and OP-PR6 may be formed through the second photoresist layer PR2 through the patterning process.

Referring to FIG. 6G, the manufacturing method of the display panel may include the etching of the preliminary pixel definition layer PDL-I to form the pixel definition layer PDL (refer to FIG. 6H) through which the light-emitting opening OP-E overlapping the first barrier wall PW-S, and an opening OP exposing the inner side surface of the second preliminary barrier wall PW-EI, are formed.

The forming of the pixel definition layer PDL may be performed by a dry etching using the second photoresist layer PR2 as a mask. Portions of the preliminary pixel definition layer PDL-I, which do not overlap the second photoresist layer PR2, may be etched and removed, and portions of the preliminary pixel definition layer PDL-I, which remain without being etched, may serve as the pixel definition layer PDL.

As an example, the light-emitting opening OP-E may be formed through the removed portion of the preliminary pixel definition layer PDL-I in an area overlapping the fourth photo opening OP-PR4. The light-emitting opening OP-E may be formed above the first barrier wall PW-S, and may overlap the first barrier wall PW-S. The opening OP may be formed through the removed portion of the preliminary pixel definition layer PDL-I in areas overlapping the fifth and sixth photo openings OP-PR5 and OP-PR6. The inner side surface of the second preliminary barrier wall PW-EI may be exposed through the opening OP.

Referring to FIG. 6H, the manufacturing method of the display panel may include removing the second photoresist layer PR2 (refer to FIG. 6G), and second etching the preliminary barrier wall PW-I (refer to FIG. 6G), to form the second barrier wall PW-E through which the barrier wall opening OP-P is defined.

The forming of the second barrier wall PW-E may be performed by wet etching the first preliminary barrier wall layer L1-I (refer to FIG. 6G) and the second preliminary barrier wall layer L2-I (refer to FIG. 6G). The forming of the second barrier wall PW-E may include etching the second preliminary barrier wall PW-EI (refer to FIG. 6G) to allow the first barrier wall PW-S to be located in the barrier wall opening OP-P. During the above processes, side surfaces of the first barrier wall PW-S, which are covered by the pixel definition layer PDL, may not be etched, and side surfaces of the second preliminary barrier wall PW-EI, which are exposed through the opening OP of the pixel definition layer PDL, may be etched.

The second barrier wall PW-E may surround the first barrier wall PW-S, and the first barrier wall PW-S may be spaced apart from the second barrier wall PW-E when viewed in the plane. The first barrier wall PW-S may include the first barrier wall layer L1-S and the second barrier wall layer L2-S, and the second barrier wall PW-E formed through the etching process may include the first barrier wall layer L1-E and the second barrier wall layer L2-E.

The wet etching process may be performed in an environment in which an etch selectivity between the first preliminary barrier wall layer L1-I and the second preliminary barrier wall layer L2-I is high. Accordingly, the second barrier wall layer L2-E of the second barrier wall PW-E may have the shape protruding toward the light-emitting opening OP-E more than the first barrier wall layer L1-E of the second barrier wall PW-E. In detail, as an etch rate of the first preliminary barrier wall layer L1-1 is greater than an etch rate of the second preliminary barrier wall layer L2-1, the first preliminary barrier wall layer L1-I may be mainly etched, or may be etched to a greater degree. Accordingly, the side surface of the first barrier wall layer L1-E of the second barrier wall PW-E may be recessed more inwardly than the side surface of the second barrier wall layer L2-E of the second barrier wall PW-E. The tip portion may be formed in the barrier wall PW by the portion of the second barrier wall layer L2-E of the second barrier wall PW-E, which protrudes more than the first barrier wall layer L1-E of the second barrier wall PW-E.

Referring to FIG. 6I, the manufacturing method of the display panel may include the etching of the preliminary sacrificial pattern SP-I (refer to FIG. 6H) to form the sacrificial pattern SP through which the sacrificial opening OP-S overlapping the light-emitting opening OP-E is formed.

The sacrificial pattern SP may be formed by wet-etching the preliminary sacrificial pattern SP-I using the pixel definition layer PDL as a mask. Portions of the preliminary sacrificial pattern SP-I, which do not overlap the pixel definition layer PDL, may be etched and removed, and portions of the preliminary sacrificial pattern SP-I, which remain without being etched, may serve as the sacrificial pattern SP.

According to the present disclosure, the process of etching the barrier wall PW using the first and second photoresist layers PR1 and PR2 (the process of forming the tip portion), the process of forming the outgassing opening OP-G, the process of forming the light-emitting opening OP-E, and the process of forming the sacrificial opening OP-S may be integrated. That is, the process of etching the barrier wall PW (the process of forming the tip portion), the process of forming the outgassing opening OP-G, the process of forming the light-emitting opening OP-E, and the process of forming the sacrificial opening OP-S may be performed using one mask, and the number of masks suitable to manufacture the display panel DP may be reduced.

Referring to FIGS. 6J and 6K, the manufacturing method of the display panel may include forming the light-emitting pattern EP and the cathode CE, which overlap the barrier wall opening OP-P when viewed in the plane. FIG. 6J shows the forming of the light-emitting pattern EP, and FIG. 6K shows the forming of the cathode CE.

Referring to FIG. 6J, the forming of the light-emitting pattern EP may include the deposition process of the light-emitting layer. As an example, the forming of the light-emitting pattern EP may include thermally evaporating the light-emitting layer on the anode AE and the pixel definition layer PDL. However, this is merely an example, and the deposition process of the light-emitting layer should not be limited thereto or thereby. The light-emitting layer may be divided into portions by the tip portion formed in the second barrier wall PW-E, and the light-emitting pattern EP and a first dummy layer D1 may be formed. The light-emitting pattern EP may be formed on the first barrier wall PW-S and the circuit element layer DP-CL, and the first dummy layer D1 may be formed on the second barrier wall PW-E. As an example, the light-emitting pattern EP may be formed on the anode AE and may overlap the barrier wall opening OP-P, and the light-emitting pattern EP may be formed to cover the anode AE and the pixel definition layer PDL.

That is, the first dummy layer D1 spaced apart from the light-emitting pattern EP may be formed in the forming of the light-emitting pattern EP. The first dummy layer D1 may include an organic material. As an example, the first dummy layer D1 may include the same material as the light-emitting pattern EP. The first dummy layer D1 may be formed with the light-emitting pattern EP through a single process, and may be separated from the light-emitting pattern EP due to the undercut shape of the second barrier wall PW-E.

Referring to FIG. 6K, the forming of the cathode CE may include a deposition process of a cathode layer. As an example, the forming of the cathode CE may include a process of sputtering the cathode layer on the light-emitting pattern EP. However, this is merely an example, and the deposition process of the cathode layer should not be limited thereto or thereby. The cathode layer may be divided into portions by the tip portion formed in the second barrier wall PW-E, and the cathode CE and a second dummy layer D2 may be formed. The cathode CE may be located on the light-emitting pattern EP and may cover the light-emitting pattern EP, and the second dummy layer D2 may be formed on the first dummy layer D1. The cathode layer may be sputtered to contact the inner side surface S1-2 of the first barrier wall layer L1-E of the second barrier wall PW-E. The second barrier wall PW-E may receive the driving voltage, and the cathode CE may be electrically connected to the second barrier wall PW-E and may receive the driving voltage.

That is, the second dummy layer D2 spaced apart from the cathode CE may be formed in the process of forming the cathode CE. The second dummy layer D2 may include a conductive material. As an example, the second dummy layer D2 may include the same material as the cathode CE. The second dummy layer D2 and the cathode CE may be formed through a single process, and the second dummy layer D2 may be separated from the cathode CE by the undercut shape of the second barrier wall PW-E.

The anode AE, the light-emitting pattern EP, and the cathode CE may be sequentially stacked in the third direction DR3. The anode AE, the light-emitting pattern EP, and the cathode CE may form the light-emitting element ED.

Referring to FIGS. 6L and 6M, the manufacturing method of the display panel may include forming the lower encapsulation inorganic pattern LIL on the cathode CE.

Referring to FIG. 6L, the forming of the lower encapsulation inorganic pattern LIL may include depositing a lower encapsulation inorganic layer LIL-I. The lower encapsulation inorganic layer LIL-I may be formed by a deposition process. The lower encapsulation inorganic layer LIL-I may be formed by a chemical vapor deposition process. The lower encapsulation inorganic layer LIL-I may be formed to cover the cathode CE and the barrier wall PW. A portion of the lower encapsulation inorganic layer LIL-I may be filled in the barrier wall opening OP-P.

Then, the forming of the lower encapsulation inorganic pattern LIL may include forming a third photoresist layer PR3. The third photoresist layer PR3 may be formed by forming a preliminary photoresist layer, and patterning the preliminary photoresist layer using a photomask. Through the patterning process, the third photoresist layer PR3 may be formed in a pattern corresponding to the light-emitting element ED.

Referring to FIG. 6M, the forming of the lower encapsulation inorganic pattern LIL may include removing portions of the lower encapsulation inorganic layer LIL-I (refer to FIG. 6L) that do not overlap the light-emitting element ED.

The removing of the portions of the lower encapsulation inorganic layer LIL-I, which do not overlap the light-emitting element ED, may be performed by a dry etching process to dry etch the lower encapsulation inorganic layer LIL-I using the third photoresist layer PR3 as a mask. The portions of the lower encapsulation inorganic layer LIL-I, which do not overlap the third photoresist layer PR3, may be removed, and remaining portions of the lower encapsulation inorganic layer LIL-I, which are not etched, may serve as the lower encapsulation inorganic pattern LIL.

The manufacturing method of the display panel may include removing the first and second dummy layers D1 and D2. The second dummy layer D2 of the 1 dummy layers D1 and D2 may be removed by a wet etching process, and the first dummy layer D1 of the dummy layers D1 and D2 may be removed by a strip process.

Referring to FIG. 6N, the manufacturing method of the display panel may include removing the third photoresist layer PR3 (refer to FIG. 6M), and forming the encapsulation organic layer OL and the upper encapsulation inorganic layer UIL (e.g., to complete the display panel DP). The encapsulation organic layer OL may be formed by coating an organic material using an inkjet method. However, it should not be limited thereto or thereby. The encapsulation organic layer OL may provide a flat upper surface thereon. Then, the upper encapsulation inorganic layer UIL may be formed by depositing an inorganic material. Accordingly, the display panel DP including the base layer BL, the circuit element layer DP-CL, the display element layer DP-OLED, and the thin film encapsulation layer TFE may be manufactured.

The processes in FIGS. 6A to 6N illustrate a process of forming a display panel corresponding to the first light-emitting area PXA-R. A process of forming a light-emitting opening corresponding to the second and third light-emitting area PXA-G, PXA-B (refer to FIG. 4) in the barrier wall PW and the pixel definition layer PDL, a process of forming the light-emitting elements corresponding to the second and third light-emitting area PXA-G, PXA-B, and a process of forming a lower encapsulation inorganic pattern covering the light-emitting elements corresponding to the second and third light-emitting area PXA-G, PXA-B may be further performed between the forming of the lower encapsulation inorganic pattern LIL and the completing of the display panel DP.

According to the present disclosure, one mask used to form the barrier wall openings corresponding to the first, second, and third light-emitting areas PXA-R, PXA-G, and PXA-B, the light-emitting opening OP-E, and the sacrificial opening OP-S and three masks used to form the lower encapsulation inorganic patterns LIL respectively corresponding to the first, second, and third light-emitting areas PXA-R, PXA-G, and PXA-B may be suitable. That is, four masks may be suitable to 1 manufacture the display panel, although the number of masks should not be limited to four.

As an example, according to one or more embodiments, one mask used to form the preliminary barrier wall openings corresponding to the first, second, and third light-emitting areas PXA-R, PXA-G, and PXA-B, the light-emitting opening OP-E, and the sacrificial opening OP-S, one mask used to form the barrier wall opening corresponding to the first light-emitting area PXA-R, one mask used to form the lower encapsulation inorganic pattern corresponding to the first light-emitting area PXA-R, one mask used to form the barrier wall opening corresponding to the second light-emitting area PXA-G, one mask used to form the lower encapsulation inorganic pattern corresponding to the second light-emitting area PXA-G, one mask used to form the barrier wall opening corresponding to the third light-emitting area PXA-B, and one mask used to form the lower encapsulation inorganic pattern corresponding to the third light-emitting area PXA-B may be suitable. That is, seven masks may be suitable to manufacture the display panel.

According to the present disclosure, the process of etching the barrier wall PW using the first and second photoresist layers PR1 and PR2 (the process of forming the tip portion), the process of forming the outgassing opening OP-G, the process of forming the light-emitting opening OP-E, and the process of forming the sacrificial opening OP-S may be integrated. That is, the process of etching the barrier wall PW (the process of forming the tip portion), the process of forming the outgassing opening OP-G, the process of forming the light-emitting opening OP-E, and the process of forming the sacrificial opening OP-S may be performed using one mask, and thus, the number of masks suitable to manufacture the display panel DP may be reduced.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present present disclosure shall be determined according to the attached claims, with functional equivalents thereof to be included therein.

What is claimed is:

1. A display panel comprising:
a base layer;
a barrier wall above the base layer, and comprising a first barrier wall and a second barrier wall;
a pixel definition layer above the base layer, and defining a light-emitting opening overlapping the first barrier wall, and surrounded by the second barrier wall in plan view; and
a light-emitting element comprising an anode above the barrier wall, a light-emitting pattern above the anode and the pixel definition layer, and a cathode above the light-emitting pattern, and contacting the second barrier wall.

2. The display panel of claim 1, wherein the second barrier wall surrounds the first barrier wall, and is spaced apart from the first barrier wall, in plan view.

3. The display panel of claim 1, wherein the first and second barrier walls comprise a conductive material.

4. The display panel of claim 1, wherein the first and second barrier walls comprise:
a first barrier wall layer above the base layer; and
a second barrier wall layer above the first barrier wall layer.

5. The display panel of claim 4, wherein the first barrier wall layer of the second barrier wall has an undercut shape with respect to the second barrier wall layer of the second barrier wall.

6. The display panel of claim 5, wherein the second barrier wall layer of the second barrier wall protrudes toward the light-emitting opening to a greater degree than the first barrier wall layer of the second barrier wall.

7. The display panel of claim 5, wherein the cathode contacts an inner side surface of the first barrier wall layer of the second barrier wall.

8. The display panel of claim 1, wherein the barrier wall defines a barrier wall opening overlapping the light-emitting opening with the first barrier wall therein.

9. The display panel of claim 8, wherein a portion of the pixel definition layer defining the light-emitting opening is in the barrier wall opening.

10. The display panel of claim 8, further comprising a lower encapsulation inorganic pattern above the cathode, covering the light-emitting element, and filled in the barrier wall opening.

11. The display panel of claim 1, further comprising a sacrificial pattern between the pixel definition layer and the anode.

12. A method of manufacturing a display panel, the method comprising:
providing a preliminary display panel comprising a base layer, a preliminary barrier wall above the base layer, an anode layer above the preliminary barrier wall, and a sacrificial layer;
etching the sacrificial layer to form a preliminary sacrificial pattern;
etching the anode layer to form an anode;
first etching the preliminary barrier wall to form a first barrier wall and a second preliminary barrier wall;
depositing a preliminary pixel definition layer above the base layer;
etching the preliminary pixel definition layer to form a pixel definition layer defining a light-emitting opening overlapping the first barrier wall, and an opening exposing an inner side surface of the second preliminary barrier wall;
second etching the preliminary barrier wall to form a second barrier wall defining a barrier wall opening; and
forming a light-emitting pattern and a cathode overlapping the barrier wall opening.

13. The method of claim 12, further comprising etching the preliminary sacrificial pattern to form a sacrificial pattern defining a sacrificial opening overlapping the light-emitting opening.

14. The method of claim 12, wherein the first barrier wall and the second barrier wall comprise:
a first barrier wall layer above the base layer; and
a second barrier wall layer above the first barrier wall layer.

15. The method of claim 14, wherein the second barrier wall layer of the second barrier wall protrudes toward the light-emitting opening to a greater degree than the first barrier wall layer of the second barrier wall.

16. The method of claim 14, wherein the forming of the light-emitting pattern and the cathode comprises:
thermally evaporating a light-emitting layer on the anode and the pixel definition layer; and
sputtering a cathode layer on the light-emitting pattern.

17. The method of claim 16, wherein the sputtering of the cathode layer comprises depositing the cathode layer to contact an inner side surface of the first barrier wall layer of the second barrier wall.

18. The method of claim 12, wherein the second etching of the preliminary barrier wall comprises etching the second preliminary barrier wall to allow the first barrier wall to be in the barrier wall opening.

19. The method of claim 12, wherein the second barrier wall surrounds the first barrier wall, and is spaced apart from the first barrier wall in plan view.

20. The method of claim 12, further comprising forming a lower encapsulation inorganic pattern on the cathode.
